(19) United States
(12) Patent Application Publication
(10) Pub. No.: US 2008/0128016 A1
(43) Pub. Date: Jun. 5, 2008

(54) Parallel Aperture Prismatic Light Concentrator

(75) Inventor: Joseph Lichy, San Jose, CA (US)

Correspondence Address: PEACOCK MYERS, P.C., 201 THIRD STREET, N.W., SUITE 1340, ALBUQUERQUE, NM, 87102, US

(73) Assignee: Silicon Valley Solar, Inc., Santa Clara, CA (US)

(21) Appl. No.: 11/936,677

(22) Filed: Nov. 7, 2007

Related U.S. Application Data
(60) Provisional application No. 60/864,920, filed on Nov. 8, 2006.

(51) Int. Cl. H01L 31/052

(52) U.S. Cl. 136/246; 136/259

(57) ABSTRACT

A radiant energy concentrator is disclosed with optical properties similar to that of the triangle prism concentrator, but with entrance and exit apertures parallel to each other. Use of the radiant energy concentrator as a component in a photovoltaic module is disclosed, and the reflectors of adjacent concentrators are preferably formed from a single piece.

### CROSS-REFERENCE TO RELATED APPLICATIONS

This application claims priority to and the benefit of the filing of U.S. Provisional Patent Application Ser. No. 60/864,920, entitled “Parallel Aperture Prismatic Light Concentrator”, filed on Nov. 8, 2006, and the specification thereof is incorporated herein by reference.

### BACKGROUND OF THE INVENTION

1. Field of the Invention (Technical Field)

The present invention relates to the concentration of electromagnetic radiation, more specifically, the concentration of light onto photovoltaic cells.

2. Background Art

Note that the following discussion refers to a number of publications and references. Discussion of such publications herein is given for more complete background of the scientific principles and is not to be construed as an admission that such publications are prior art for patentability determination purposes.

The concentration of electromagnetic radiation through the use of optical devices has many uses. In various forms electromagnetic radiation concentrators, or light concentrators, can be used to amplify signals—as in the fields of photonics and astronomy—or to more easily extract the energy contained in the radiation—as in solar energy.

Within the field of solar energy, concentration can be used to achieve higher temperatures than are otherwise achievable, or to allow a greater amount of electricity to be generated from a given amount of solar-electric or photovoltaic (PV) material. PV material is generally the largest cost component in solar electric systems, so it is desirable to reduce the amount of this material required to produce a given amount of electrical energy.

Many solar concentrators have been proposed for PV applications; however, acceptance of these devices has been limited. The reason for this is that concentrators that concentrate light to a great degree, increasing the flux by more than about three times, must be pointed directly at the sun to a high degree of accuracy in order to function. This requires expensive tracking equipment that must also be maintained. Furthermore, these concentrators cannot collect light that has been scattered by the atmosphere, so they are not effective in climates that experience significant cloudiness. Lower concentration concentrators (below 3×) overcome many of these problems; however, because they reduce the amount of required PV material by a lesser amount, they must be designed in a manner consistent with low cost manufacturing techniques. If not, the added costs may overwhelm the savings from concentration.

One light concentrator proposed for use in low concentration applications is the prismatic concentrator described by David Roy Mills in Japanese Kokai Patent #54-18762, entitled “Focusing and Dispersing Device of Radiation”. Many other devices have been proposed, but the prismatic concentrator has a number of interesting characteristics that make it attractive for use as a PV concentrator. First, it produces a uniform illumination at the target surface (exit) of the concentrator. This is unusual in concentrators, and is of great benefit in PV applications because it reduces the need for large conductors on the PV device and reduces localized heating issues. Second, because it is a solid device, it has no cavities which need to be sealed or evacuated, or any inner surfaces that need to be maintained. Third, when arrayed as shown in FIG. 4 of Japanese patent #54-18762 it can be integrated into a PV module with a flat front surface, which simplifies maintenance. Finally, it is an asymmetric concentrator, which makes it particularly useful for use on flat and north facing roofs as described in commonly owned U.S. patent application Ser. No. 11/725,665, “Apparatus and Method for Construction and Placement of a Non-Equatorial Photovoltaic Module”.

The prismatic concentrator is not easily manufactured, however, and this has limited its success in commercial applications. As described by Mills, the prismatic concentrator requires the placement of photovoltaic cells in multiple parallel planes. In addition, the wires interconnecting these cells must be bent to very tight angular tolerances, and placement of cells along those wires must likewise meet very tight tolerances. The configuration is incompatible with both traditional stringing processes commonly used in the PV industry or with pick-and-place equipment used for electronics board assembly.

While prismatic concentrators with curved secondary reflectors have been previously proposed (e.g. Mills and Giutronich, “Ideal Prism Solar Concentrators”, Solar Energy, Vol. 21 pp. 423-430, 1978), these devices add a photovoltaic component to a thermal collector. As a thermal collector the optic is necessarily filled with a working fluid which is known to interfere with the performance and reliability of a photovoltaic module. In addition, the required presence of an insulator located under the photovoltaic module is problematic as the performance of solar cells degrades with temperature.

It is therefore desirable to at address the concerns referred to herein to produce a more cost-effective PV module.

### SUMMARY OF THE INVENTION

### Disclosure of the Invention

The present invention comprises a radiation concentrator comprising an entrance aperture, a flat primary reflector disposed at an angle to the entrance aperture, a curved secondary reflector comprising a surface described by a circular segment; and a solar cell disposed between the primary reflector and the secondary reflector. The solar cell is preferably parallel to the entrance aperture. The entrance aperture preferably comprises a portion of a front surface of a solar module. The space defined by the entrance aperture, the primary reflector, the curved secondary reflector, and the solar cell preferably comprises a clear refractive filler material. The filler material preferably comprises a refractive index greater than 1, and preferably comprises plastic. A circle comprising the circular segment preferably has a center coincident with an endpoint of the primary reflector. The solar cell preferably extends approximately from the endpoint to an endpoint of the curved secondary reflector. The primary reflector and a curved secondary reflector of an adjacent radiation concentrator are preferably formed from a single piece of material.

The present invention is also a method of concentrating radiation, the method comprising the steps of accepting radiation into a refracting material, reflecting the radiation from a flat first reflector, reflecting the reflected radiation from a curved second reflector, the curved second reflector comprising a surface described by a circular segment, and subsequently absorbing the reflected light with a solar cell. The refracting material preferably comprises plastic. The method preferably further comprises the step of disposing the solar cell between the first reflector and the curved second reflector such that a surface of the solar cell is coincident with a radius of the circular segment.

The present invention is also a solar module comprising a plurality of solar concentrators, each concentrator comprising a flat first reflecting surface, a curved second reflecting surface, a solar cell, and a refracting material, wherein adjacent concentrators comprise a common element, the element comprising a first reflecting surface from a first solar concentrator and a second curved reflecting surface from a second solar concentrator adjacent to the first solar concentrator. The top surface of the module preferably comprises top surfaces of the refracting material in each solar concentrator. The surfaces of the plurality of solar cells are preferably parallel to the top surface of the module. The module preferably comprises a cover disposed on the top surface. The refracting material preferably comprises plastic. The curved second reflecting surface preferably comprises a circular segment. The center of a circle encompassing the circular segment is preferably coincident with an endpoint of the first reflecting surface. The element preferably comprises an empty space between the first reflecting surface and the second reflecting surface.

One embodiment of the present invention consists of a modification of the prismatic concentrator described above, comprising a second reflective element that preferably directs light to a new exit location that is parallel with the collector aperture. This modification preferably enables the concentrator element to be arrayed and optically coupled to a plurality of photovoltaic cells, each electrically coupled to form a PV module. In this embodiment the PV cells are preferably coplanar, consistent with the requirements of traditional stringing and pick-and-place equipment. Furthermore, because misalignment of the cells does not prevent proper module assembly, greater tolerances in the placement of PV cells can be accommodated.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention. In the drawings:

FIG. 1 is a detailed side-view of a prismatic concentrator module of the prior art;

FIGS. 2A-2D is a ray diagram showing ray traces in the prismatic concentrator of the prior art;

FIG. 3 is a side view of the parallel aperture prismatic light concentrator of the present invention;

FIGS. 4A-4D show ray traces of the parallel aperture prismatic light concentrator of the present invention;

FIGS. 5A and B are luminance maps of the prior art prismatic concentrator and the parallel aperture prismatic concentrator of the present invention;

FIG. 6 is a side view of a preferred embodiment of an array of coplanar parallel aperture prismatic light concentrators of the present invention in a photovoltaic module; and

FIG. 7 is a perspective view of a reflective element of a parallel aperture prismatic light concentrator photovoltaic module.

### REFERENCE NUMERALS IN DRAWINGS

100 Prismatic concentrator photovoltaic module (prior art)
110 Front glass
120 Refractive filler material
130 Reflector
140 PV cell
150 PV Cell electrical connections
210 Prior Art Prism angle (Φ)
220 Prior Art Light ray external incident angle (θᵢ)
230 Prior Art Light ray internal incident angle (θ₁)
300 Parallel aperture prismatic light concentrator
310 Entrance aperture
320 Primary reflector
330 Exit aperture
340 Secondary reflector
350 Refractive filler material
360 Proximal endpoint of primary reflector 320
410 Prism angle (Φ)
420 Light ray external incident angle (θᵢ)
430 Light ray internal incident angle (θ₁)
600 Coplanar prismatic concentrator photovoltaic module
610 Glass
630 Reflective element
640 PV cell
650 Frame

### DESCRIPTION OF THE PREFERRED EMBODIMENTS

### Best Modes for Carrying Out the Invention

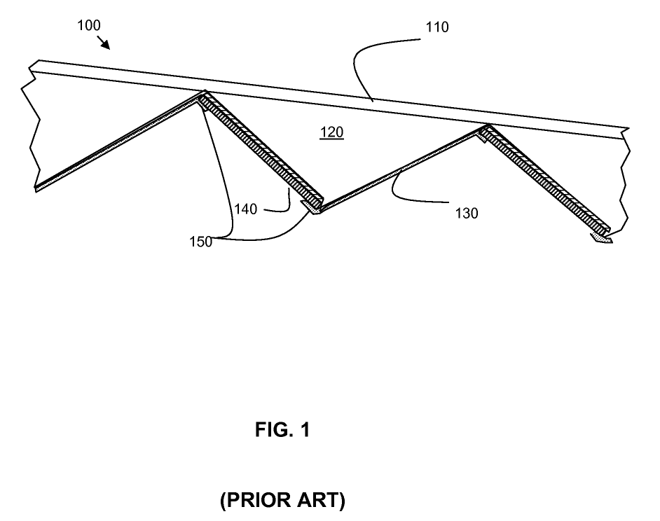

FIG. 1 shows a prior art triangular prism concentrator (TPC) array photovoltaic module 100 known in the prior art. Module 100 is made up of front glass 110 having a flat front surface, reflector 130 and PV cells 140 having PV cell electrical connections 150. Front glass 110, reflector 130, and PV cell 140 are arranged to produce a triangular trough between them. This trough is filled with clear refractive material 120. The single front glass 110 is combined with a plurality of reflectors 130 and cells 140 to produce a plurality of prisms in a triangular prism concentrator.

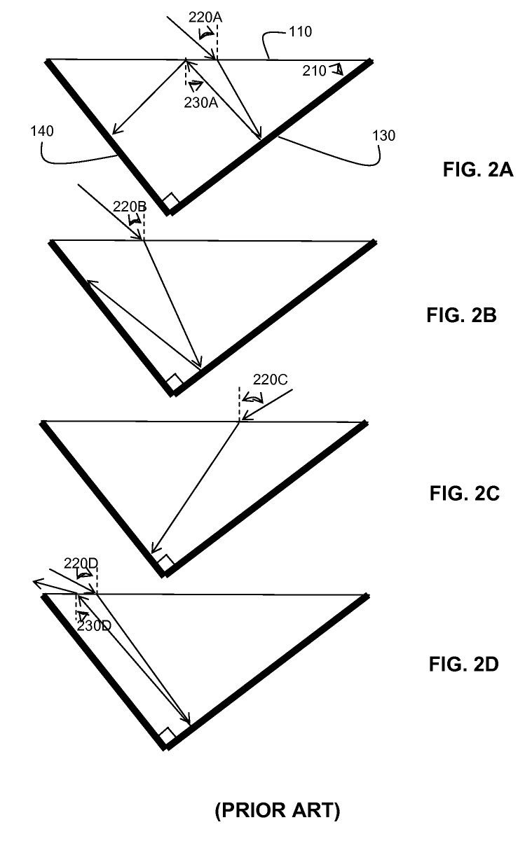

FIGS. 2A-2D show a simplified cross-sectional view of one of the triangular prisms shown in FIG. 1 with exemplary light ray traces to illustrate the function of this component. The prism in the illustration has an index of refraction of 1.5, and the angle 210 between front surface 110 and the reflector 130 is 38°. The other angles are 90° and 52°, respectively. PV cell 140 is disposed at a right angle to the reflector. In FIG. 2A a light ray is incident on prism front surface 110 at incident angle θᵢ 220 of 45°. It is refracted at surface 110 because the index of refraction of the triangular prism. The ray then is reflected off reflector 130 and transits the prism a second time, intersecting surface 110 at angle θ₁ 230A of 48°. Angle 230A is greater than the critical angle θ_{c} of 41.8° required for total internal reflection, so the ray reflects off surface 110, transits the prism a third time, and impinges on PV cell 140 in order to be converted into electricity.

In FIG. 2B, the light ray is again incident on surface 110 at angle θᵢ 220B of 45°. It is refracted at that surface and transits the prism to reflect off reflector 130. In this case, the reflected ray impinges directly on PV cell 140 without any further reflections or refractions.

In FIG. 2C, the ray is incident on surface 110 at angle θᵢ 220C of 70° from the right. After refraction it is directed directly to PV cell 140.

In FIG. 2D, the light ray is incident on surface 110 at angle θᵢ 220D of 70° from the left. After refraction it transits the prism, reflects off surface 130, transits the prism a second time and is incident on surface 110 with incident angle θ₁ 230D of 37°. Angle 230D is less than the critical angle for total internal reflection θ_{c} of 41.8°, so the light ray is refracted and escapes the concentrator. We say this light is rejected by the concentrator. The rays of FIGS. 2A-2C were all accepted, meaning that they reached PV cell 140 for potential conversion into electricity.

From the examples of FIGS. 2A-2D, it can be seen that essentially all light incident from the right side is accepted by the triangular prism concentrator. Light incident from the left, however, may be accepted or rejected depending on the magnitude of the incident angle θᵢ. If reflections off front surface 110 are neglected, then there is some angle θₐ between 220A and 220D for which all light incident with θᵢ<θₐ is accepted, and all light incident with θᵢ>θₐ is rejected. We call this angle θₐ the acceptance angle. The acceptance angle can be computed based on the prism angle Φ 210 and the index of refraction n of each prism. The condition for acceptance is that the angle of incidence of the ray on surface 110 after reflecting off reflector 130 (θ₁) is greater than the critical angle for total internal reflection θ_{c}. Using geometric optics the following relationships can be derived:

θ₁=2Φ−a sin(sin(θᵢ)/n) Eq. 1

θ_{c}=a sin(1/n) Eq. 2

The condition for determining the acceptance angle is:

θ₁=θ_{c} Eq. 3

Substituting equations 1 and 2 into equation 3 we get:

a sin(1/n)=2Φ−a sin(sin(θₐ)/n) Eq. 4

θₐ=a sin [n sin(2Φ−a sin(1/n))] Eq. 5

Φ=[a sin(sin(θₐ)/n)+a sin(1/n)]/2 Eq. 6

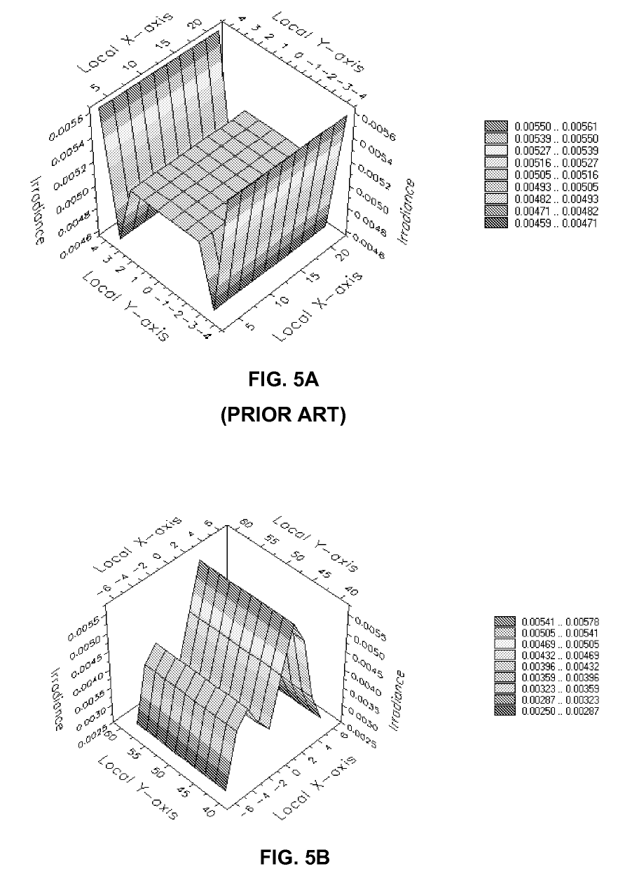

The triangle prism concentrator of FIGS. 1 and 2 was originally described by David Mills in Japanese Kokai patent 54-18762. It has many beneficial properties. Its thickness is less than the width of the target for any concentration, significantly thinner than other traditional concentrators. Also, because it has no curved refractive or reflective surfaces it does not cause light to converge on a point on the target, as shown in FIG. 5A. It is also asymmetric, collecting light from one horizon to the acceptance angle.

However, the relative position of the PV cells in the triangle prism concentrator makes it difficult to manufacture. Specifically, the placement of the cell between two corners of a triangle makes placement precision critical. The fact that the cells of a triangle prism concentrator module are not located in a common plane means that traditional stringing and lamination techniques cannot be used. The electrical connection between the cells must be bent to follow the profile of the concentrator and connect between terminals on adjacent cells, further complicating the manufacturing process.

It would be desirable to create a concentrator with similar optical properties to the triangle prism concentrator, but preferably with the target parallel to the front surface of the concentrator. In this case a module could optionally be constructed with a flat front surface and all cells of the module located in a common plane.

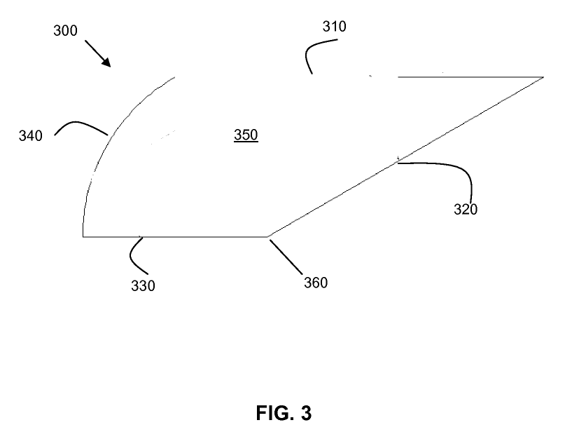

FIG. 3 shows one embodiment of the parallel aperture prismatic light concentrator 300 of the present invention. It preferably comprises clear, flat entrance aperture 310, which is preferably coincident with a front surface of a module, flat primary reflector 320 disposed at an angle to entrance aperture 310, curved secondary reflector 340 opposite primary reflector 320 and clear, flat exit aperture 330 preferably parallel to entrance aperture 310 and defined by the proximal endpoints of primary reflector 320 and secondary reflector 340. The body of parallel aperture prismatic light concentrator 300 preferably comprises clear refractive filler material 350, which preferably comprises a refractive index greater than 1, and preferably comprises plastic. Secondary reflector 340 preferably describes a circular arc centered on the proximal endpoint 360 of primary reflector 320 with a radius equal to the width of exit aperture 330; that is a line drawn from the center to the distal edge of secondary reflector 340 preferably forms a right angle with primary reflector 320. Although the curve of secondary reflector 340 is preferably non-parabolic, it may optionally be described by any geometry that directs all, or a large fraction of, light impinging on it (after reflecting off either primary reflector 320 or entrance aperture 310, e.g. through total internal reflection) to exit aperture 330.

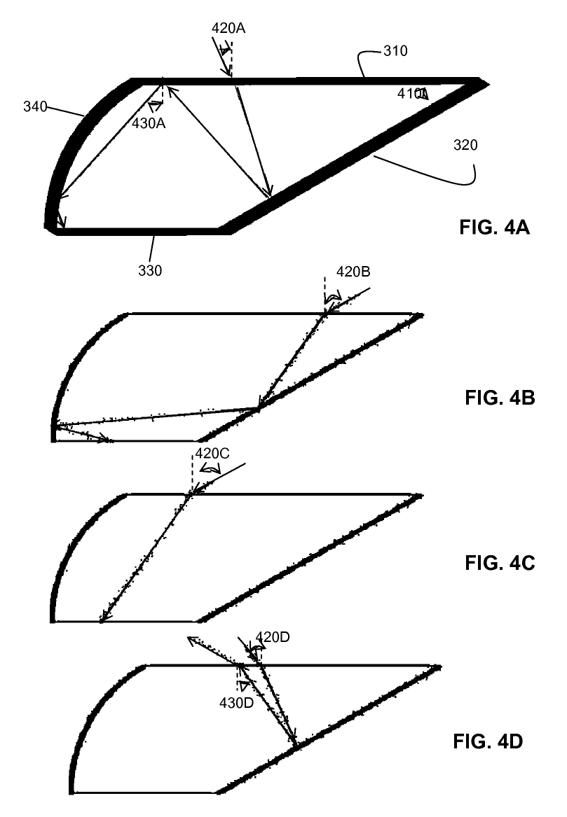

FIGS. 4A-4D show the operation of the parallel aperture prism concentrator. The diagrams are analogous to FIGS. 2A-2D for the prior art triangle prism concentrator, except that in FIGS. 4A and 4B the light ray first encounters secondary reflector 340 before reaching exit aperture 330. angles Φ 410, θᵢ 420A-420D, and θ₁ 430A, 430D correspond respectively to angles 210, 220A-220D, 230A, and 230D of FIG. 2; the equations described above still hold. Thus, for an example value of n=1.5, the following table provides some parameters of the present invention:

| Prism Angle 410 | Acceptance Angle | Concentration Factor |
|---|---|---|
| 20 | −2.7 | 2.92 |
| 25 | 12.3 | 2.37 |
| 30 | 27.9 | 2.00 |
| 35 | 45.1 | 1.74 |
| 40 | 68.0 | 1.56 |

If secondary reflector 340 is a portion of a circle then the surface normal at any point along its surface is a straight line passing through that point and the center of the circle. If the center of the circle is coincident with the proximal end of primary reflector 320, then any light ray passing above that center will preferably be reflected back so as to pass below that center, and out through exit aperture 330. Thus we see that all light collected by the triangle prism concentrator is also collected by the parallel aperture prism concentrator; it has the same acceptance angle. That is, light incident at any angle from one horizon to an acceptance angle above the opposite horizon is preferably collected. It can also be seen from FIGS. 3 and 4 that the thickness of the parallel aperture prism concentrator is preferably advantageously approximately the same as that of the prior art triangle prism concentrator, thereby improving manufacturability.

FIGS. 5A and 5B are irradiance maps produced by Fred™ Optical modeling software from Photon International, LLC, Tuscon, Ariz. From the two charts it can be plainly seen that the irradiance varies by less than 10% across the target of the prior art triangle prism concentrator (FIG. 5A), but by a factor of 2 (100%) for an embodiment of the parallel aperture prism concentrator of the present invention (FIG. 5B). Therefore, the use of curved secondary reflector 340 increases the variance of the convergence of light on the target. However, this trade off of optical performance versus manufacturability is likely acceptable, as a factor of 2 variation is still significantly lower than what is experienced in other traditional concentrators, such as compound parabolic concentrators and Fresnel lenses. Further, a factor of 2 variation is not large enough to result in problems typically seen with high variance concentrators, such as current crowding, local heating, and high UV flux damage.

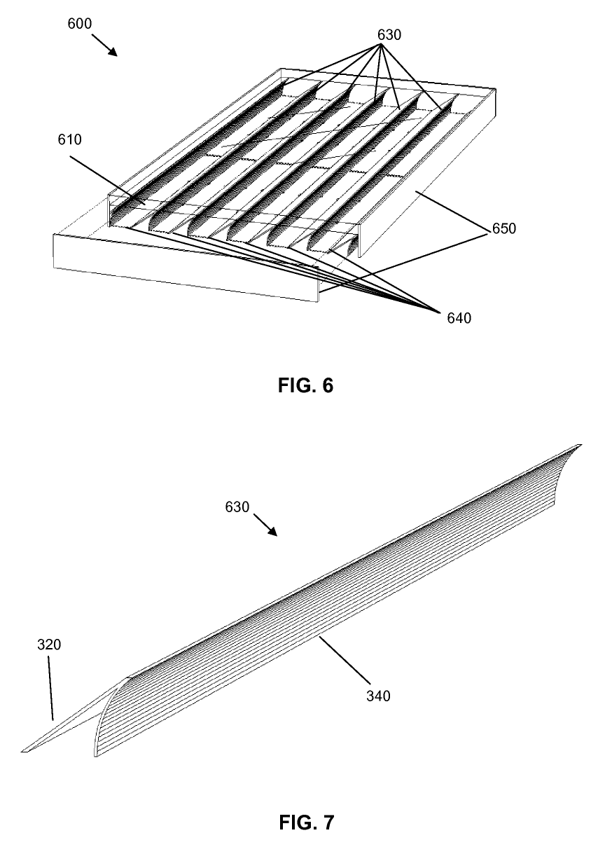

FIG. 6 shows an embodiment of the present invention in which a plurality of parallel aperture prism concentrators are arrayed in a module with photovoltaic cells 640 preferably optically coupled to the exit aperture. In this embodiment the concentrators are preferably formed by reflective elements 630 that are preferably constructed to include primary reflector 320 of one concentrator and secondary reflector 340 of the immediately adjacent concentrator as a single piece. The space between the reflectors is then preferably filled with a clear refractive material, such as a thermoplastic material that may be cast in the module, or alternatively a curable resin that may be cast and chemically modified to enhance stability. In some embodiments it may be advantageous to cover the front of module 600 with a sheet of glass 610 and support module 600 in frame 650.

FIG. 7 shows a perspective view of reflective element 630 that combines primary reflector 320 of one concentrator and secondary reflector 340 of the immediately adjacent concentrator. Reflective element 630 may comprise molded plastic coated with a reflective surface, or may alternatively be formed from reflective aluminum sheet, cast from aluminum or other metal, or be formed or coated using any means known in the art. The area under the inverted “V” of refractive element 630, located between primary reflector 320 of one concentrator and secondary reflector 340 of the immediately adjacent concentrator, is preferably empty.

In many systems, such as thermal collectors designed at least in part for heat absorption, insulation is required to be disposed under support module 600 to keep temperatures in the optimal operating range for the thermal collector. However, such insulation would compromise the performance of the present invention, because the performance of solar cells is greatly degraded at high temperatures. For example, for thermal collectors, high temperatures, typically greater than or equal to about 100° C., are desirable. However, solar cell performance drops off at about 0.5% per degree. Since a typical operating temperature for a photovoltaic cell is about 40° C., a large degradation in performance of at least 30% would occur.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents and publications cited above are hereby incorporated by reference.

What is claimed is:

1. A radiation concentrator comprising:
an entrance aperture;
a flat primary reflector disposed at an angle to said entrance aperture;
a curved secondary reflector comprising a surface described by a circular segment; and
a solar cell disposed between said primary reflector and said secondary reflector.

2. The radiation concentrator of claim 1 wherein said solar cell is parallel to said entrance aperture.

3. The radiation concentrator of claim 1 wherein said entrance aperture comprises a portion of a front surface of a solar module.

4. The radiation concentrator of claim 1 wherein a space defined by said entrance aperture, said primary reflector, said curved secondary reflector, and said solar cell comprises a clear refractive filler material.

5. The radiation concentrator of claim 4 wherein said filler material comprises a refractive index greater than 1.

6. The radiation concentrator of claim 4 wherein said filler material comprises plastic.

7. The radiation concentrator of claim 1 wherein a circle comprising said circular segment has a center coincident with an endpoint of said primary reflector.

8. The radiation concentrator of claim 7 wherein said solar cell extends approximately from said endpoint to an endpoint of said curved secondary reflector.

9. The radiation concentrator of claim 1 wherein said primary reflector and a curved secondary reflector of an adjacent radiation concentrator are formed from a single piece of material.

10. A method of concentrating radiation, the method comprising the steps of:
accepting radiation into a refracting material;
reflecting the radiation from a flat first reflector;
reflecting the reflected radiation from a curved second reflector, the curved second reflector comprising a surface described by a circular segment; and
subsequently absorbing the reflected light with a solar cell.

11. The method of claim 10 wherein the refracting material comprises plastic.

12. The method of claim 10 further comprising the step of disposing the solar cell between the first reflector and the curved second reflector such that a surface of the solar cell is coincident with a radius of the circular segment.

13. A solar module comprising:
a plurality of solar concentrators, each concentrator comprising a flat first reflecting surface, a curved second reflecting surface, a solar cell, and a refracting material;
wherein adjacent said concentrators comprise a common element, said element comprising a first reflecting surface from a first solar concentrator and a second curved reflecting surface from a second solar concentrator adjacent to said first solar concentrator.

14. The solar module of claim 13 wherein a top surface of said module comprises top surfaces of said refracting material in each solar concentrator.

15. The solar module of claim 14 wherein surfaces of said plurality of solar cells are parallel to said top surface of said module.

16. The solar module of claim 14 further comprising a cover disposed on said top surface.

17. The solar module of claim 13 wherein said refracting material comprises plastic.

18. The solar module of claim 13 wherein said curved second reflecting surface comprises a circular segment.

19. The solar module of claim 18 wherein a center of a circle encompassing said circular segment is coincident with an endpoint of said first reflecting surface.

20. The solar module of claim 13 wherein said element comprises an empty space between said first reflecting surface and said second reflecting surface.
